(19) United States
(12) Patent Application Publication
(10) Pub. No.: US 2015/0301566 A1
(43) Pub. Date: Oct. 22, 2015

(54) Portable Device Stand With Incremental Adjustment Capabilities

(71) Applicant: Christopher Alexander Santiago, Virginia Beach, VA (US)

(72) Inventor: Christopher Alexander Santiago, Virginia Beach, VA (US)

(21) Appl. No.: 14/258,055

(22) Filed: Apr. 22, 2014

(51) Int. Cl. G06F 1/20; F16M 11/40; H05K 5/02; G06F 1/16; F16M 11/20

(52) U.S. Cl. CPC G06F 1/203; G06F 1/1613; F16M 11/2057; H05K 5/0204; F16M 11/40

(57) ABSTRACT

A portable device stand includes an upper surface, a lower surface, and one or more expandable apparatus. Voids are included in the upper surface to provide ventilation which assist in cooling portable electronic devices. The stand has the ability to be incrementally adjusted using one or more expandable apparatus. This feature allows a user to choose a specific setting based on their needs. Using the expandable apparatus allow a user to adjust their device stand in a variety of angles in a single step. A lower surface, which is connected to the upper surface by one or more expandable apparatus, may be used for storage.

### BACKGROUND

The present embodiment generally relates to portable device stands, and more particularly to a stand for a laptop computer.

### PRIOR ART

Many portable electronic devices, such as laptop computers, are designed to be versatile, portable, and useful in situations where a standard size device may not be practical.

A laptop computer, or laptop, refers to a portable computer that is small enough to comfortably fit in someone's lap. Because a laptop computer contains similar processors to their desktop counterparts, only in smaller enclosures, there becomes an apparent need to dissipate heat.

Part of the problem is that the internal space, where the main CPU hardware is located, is also relatively small, which may result in insufficient airflow. This allows heat little chance to escape when used on many surfaces, or on a lap. Due to heat transfer, the excess heat generated by an electronic device may be absorbed by the components within the device itself, which causes a rise in the internal temperature.

Another potential problem involves the height of the monitor relative to a normal person's eye-level, where in some cases a differential in height may cause neck strain to the user. Some laptop stand manufacturers have attempted to solve this problem with various designs, but where the attempts solved the aforementioned height problem, they sacrificed portability and often require the need for an external keyboard. These elaborate systems are not very practical and are often cumbersome, making the once practical laptop computer much less portable.

Another shortcoming with regards to laptop computers is their keyboards, which are largely parallel to the surface that they rest upon. This means that the keyboard is not at an optimized or ergonomic typing angle when sitting on a flat surface. Using laptop computers without additional accessories is proven to have negative effects on one's health, where users often experience neck and/or wrist strain as a result of improper posture. There are no device stands that provide the user with a means to incrementally adjust the height and the angle of every corner of said stand. This shortcoming denies one the ability to choose a specific setting to suit their needs.

Attempts have been made to solve a few of the aforementioned issues but these attempts yielded devices that often-sacrificed portability and overall flexibility. Other attempts yielded laptop stands that are intended for use on laps, but are substantially larger than the computers they support, which hinders the portability factor and fails to raise the laptop computer to eye-level.

The laptop computer stands on the market today are designed to solve single problems, often not addressing more than one problem a user may encounter while using a portable device.

A first example of a computer stand is U.S. Ser. No. 10/657,329 Issued to Moss on Apr. 1, 2004 (Hereinafter the “359 patent”), which has a limited range of motion due to small hinges. patent 359 does not extend the portability of the laptop computer. This computer stand does not have room for storage. patent 359 does not allow a user to adjust the laptop desk to compensate for uneven surfaces nor does it provide the opportunity to provide an eye-level view of the laptop computer. One may not adjust all four corners of the platform on this stand for incremental adjustments.

U.S. patent Ser. No. 10/246,700 Issued to MacEachem on January 2004

(Hereinafter the “700 patent”) offers a limited range of forward-tilt motion using stackable risers which are small, potentially easy to lose, and do nothing to extend the portability of laptop computers. No useful storage space is created as a result of its tilt and the system fails to provide an option for eye-level computer use. One may not adjust all four corners of the platform on this stand for incremental adjustments.

U.S. patent Ser. No. 11/556,970 Issued to Sparling on May 31, 2007 (Hereinafter the “970 patent”) is a fairly complex system for using a laptop which include multiple moving parts. The overall device is much larger than a laptop computer, making it largely non-portable. patent 970 may be too cumbersome to use in most public scenarios. One may not adjust all four corners of the platform on this stand for incremental adjustments.

U.S. patent Ser. No. 12/754,226 Issued to Trang on Mar. 20, 2012 (Hereinafter the “226 patent”) offers a relatively complex system which achieves no function beyond existing laptop stands. This stand involves multiple moving parts creating a range of motion resulting in a forward-angle tilt, which is found in many other examples. patent 226 does not create useful storage space as a result of its angle-tilt and it also fails to raise the laptop to eye-level, which has been proven to reduce muscle strain. One may not adjust all four corners of the platform on this stand for incremental adjustments.

U.S. patent Ser. No. 12/006,781 Issued to Marion on Nov. 20, 2008 (Hereinafter the “781 patent”) offers a complex system intended to be used in bed. The laptop desk uses a series of pegs to offer forward and backwards tilt capability, which is achieved by other laptop desks using simpler systems. The unit is not portable and isn't practical for use outside of the home, severely limiting its use as a stand for a portable device. One may not adjust all four corners of the platform on this stand for incremental adjustments.

### DETAILED DESCRIPTION & OPERATION

The following detailed description of the invention refers to the accompanying drawings. The same reference numbers in different drawings identify the same or similar elements. Also, the following detailed description does not limit the invention. Instead, the scope of the invention is defined by the appended claims and equivalents.

### Exemplary Portable Device Stand

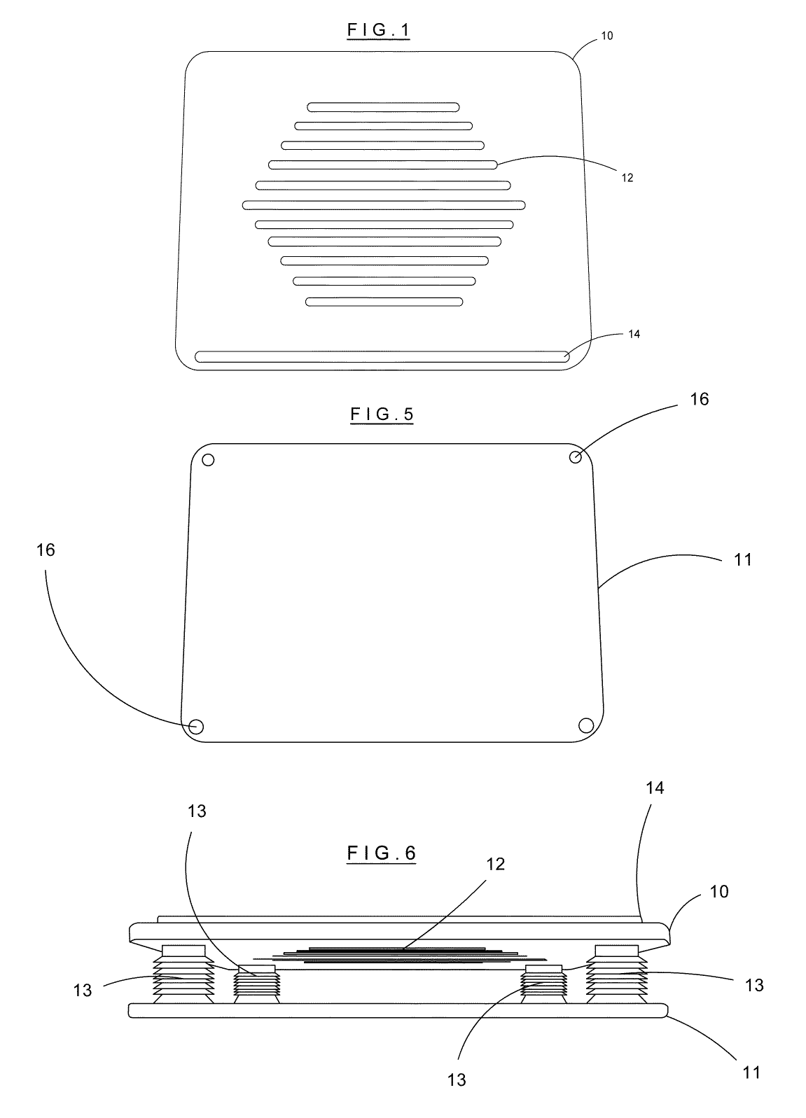

One embodiment of the portable device stand is illustrated in FIG. 1 (top view), FIG. 6 (front view) and FIG. 5 (bottom view). An upper surface or upper deck 10 connected to a lower surface or lower deck 11 which may be connected in a largely parallel manner by one or more adjustable apparatus or lifters 13. The upper deck 10 and lower deck 11 are equally sized to provide a stable surface for portable devices, such as a laptop computer 17 (not pictured). Shown also are a plurality of cooling vents seen in the upper deck 10. The upper deck 10 also may have one or more stop bars 14, which aid in keeping a portable device secure during use. The lower deck 11 may have one or more gripping discs 16 to prevent the embodiment from sliding during use. The gripping discs 16 which may be used on the lower deck 11 may also be used on the upper deck 10 to prevent a portable device from sliding during use. The gripping discs 16 may be used in combination with the stop bar(s) 14 on the upper deck 10 to prevent portable devices from sliding during use.

The portable device stand as seen in FIG. 2 (perspective view from left) FIG. 4 (perspective view from right-rear) and FIG. 7 (perspective view from right) shows the portable device stand in a forward-tilt state, where one or more adjustment apparatus, or lifter(s) 13, are used to provide incremental-adjustment capabilities. Gripping discs 16 may be used as an added precaution when the upper deck 10 is used in full-tilt mode, but this is not required, as the stop bar 14 adds an adequate level of security. Alternatively, the upper deck 10 may be positioned parallel to the horizon, creating a level surface for a laptop 17 shown in FIG. 7. At this point the lower deck 11 may be positioned on an uneven surface, whereby the lifters 13 are compressed or expanded, depending on the user preference, to create the desired angle.

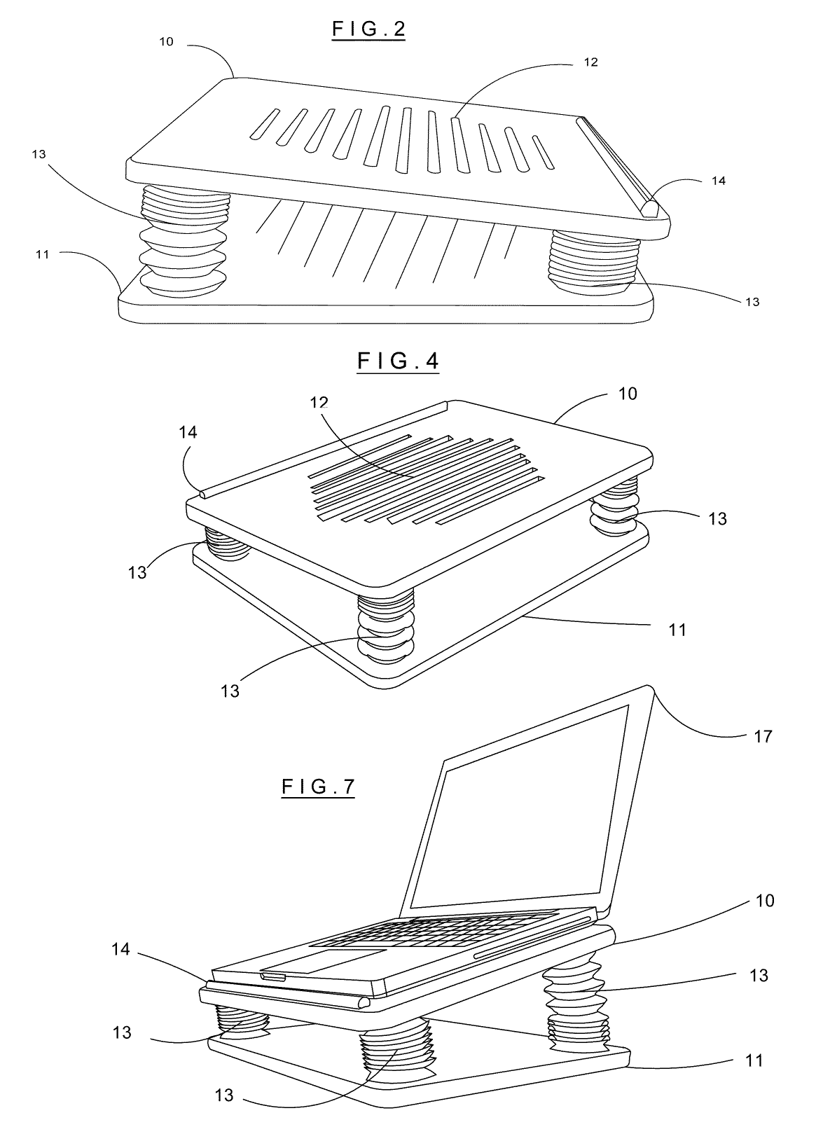

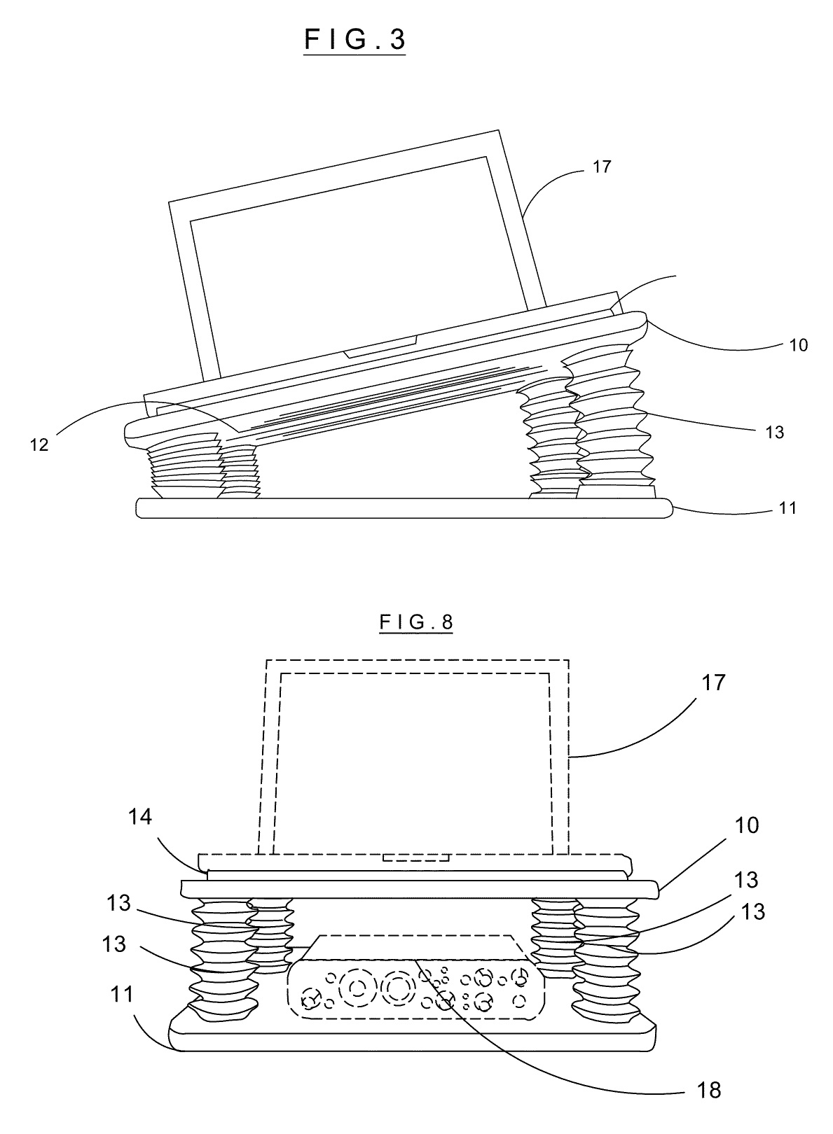

FIG. 3 (front view during extreme left-tilt) shows the portable device stand in an extreme left-tilt scenario, where the upper deck 10 is positioned such that the right end is higher than the left while the lower deck 11 remains level. Stop bars 14 may be used in this scenario for a layer of added protection in combination with gripping discs 16. An alternative scenario provides an ability to adjust to a surface which may not be longitudinally level, whereby the lower deck 11 is angled to accommodate the un-level surface, while the upper deck 10 remains level, and, or, tilted forward.

FIG. 8 (front view during full-extension) shows a portable device stand where the upper deck 10 and lower deck 11 are at their maximum distance apart, meaning the lifter(s) 13 are fully stretched, placing the portable device, such as a laptop 17, at a higher altitude. Pictured also is an audio interface 18 for size comparison, illustrating the ability to store items on the lower deck 11 during use.

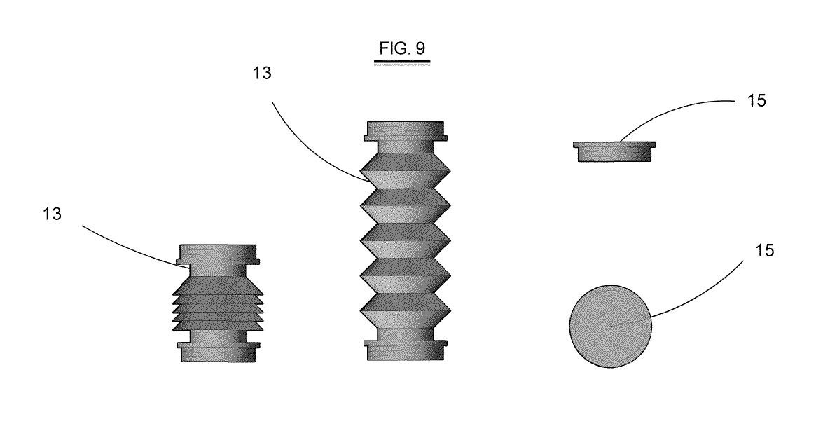

FIG. 9 offers a closer look at the adjustment apparatus, or the lifter 13 as previously mentioned. One embodiment of the lifter 13 may involve a threaded male end portion that may be mechanically joined with a female end-cap, or cap 15. The present embodiment proposes that the cap 15 be joined with the upper deck 10 and the lower deck 11, where a variety of methods may be used to provide a permanent connection between the cap 15 and the upper and lower decks 10 and 11 respectively. Once the cap 15 is joined to the upper 10 and lower 11 decks, the lifter(s) in its expanded state 13 may be inserted into the cap 15 and tightened by hand, in either a clockwise or counterclockwise manner, until a firm connection is achieved. A user may also wish to uninstall a lifter 13 by reversing this process, removing it from the upper 10 and lower 11 decks. The lifter 13 may also form a permanent connection with the upper deck 10 and lower deck 11 with the use of a strong adhesive, epoxy, or some other type of bonding agent capable of withstanding the mechanical stress. There are also other methods that may be used to provoke a temporary connection between the lifter(s) 13 and the upper and lower surface 10 and 11 respectively, which give a user the ability to replace a lifter 13. The lifter 13 may be made from a variety of materials, however plastic was chosen for this embodiment for its unique properties and its ability to be molded. The design enables each segment, one or many, to overlap, which creates incremental adjustment capabilities. Incorporating an accordion-style design, where each increment can support the weight of a portable device, creates this incremental-adjustment capability.

### CONCLUSION, RAMIFICATIONS, AND SCOPE

Thus the reader will see that the embodiment of the Portable Device Stand with Incremental Adjustment Capabilities, hereafter referred to as a portable device stand, combines usefulness, portability, pleasing atheistic and enables one with the novel ability to adjust each corner incrementally.

While the above description contains much specificity, these should not be construed as limitations on the scope, but rather as an exemplification of a plurality of embodiments thereof. Many other variations are possible. For example, a portable stand may include none of the safety mechanisms suggested in the figures (i.e. stop bar or gripping discs) or, may have many more than suggested. Another variation may include a lower deck, which is smaller or larger than the upper deck. Another example may contain only one lifter device, where another example may include a plurality of lifters. One may construct a laptop stand where the expandable device is affixed to the upper and/or lower surface using any number of fastening alternatives. One may construct a laptop stand where the expandable device adheres to the upper and/or lower surfaces using adhesives such as an epoxy, or by some other means. Another example may not contain cooling vents or the same amount of cooling vents shown in the figures. One may use the portable device stand for multiple devices, where each stand is sized accordingly.

One may use this configuration to supply the optimal angle for some other device, such as a musical keyboard, or some other control surface. The aforementioned embodiments may be constructed from various materials that are capable of being used as a support structure and can vary in color. Accordingly, the scope should be determined not by the embodiment(s) illustrated, but by the appended claims and their legal equivalents.

I claim:

1. In a portable device stand:
a substantially planar upper surface made from a predetermined material, a connection between said upper surface and one or more expandable apparatus, a connection between said expandable apparatus and a substantially planar lower surface made from a predetermined material.

2. The portable device stand of claim 1, wherein said upper and lower surface may be constructed from materials such as plastic (polyethylene, acrylic, recycled plastics), wood, glass, or some other material that is capable of meeting the physical demands required to accommodate various portable devices.

3. The portable device stand of claim 1, wherein voids are incorporated into the upper surface to assist in cooling the device by providing improved airflow.

4. The portable device stand of claim 1, wherein anti-slip inserts are installed onto the upper surface and onto the lower surface to ensure grip.

5. The portable device stand of claim 1, wherein anti-slide bars, or tabs, are used to further assist in securing devices on the upper and, or, lower surfaces.

6. In a laptop stand:
a mostly planar upper and lower surface, where said upper and lower surfaces are connected to a plurality of expandable apparatus, where said expandable apparatus provide incremental adjustment capabilities by incorporating overlapping segments, which may be expanded or collapsed, whereby giving one the ability to adjust the height of each individual apparatus in a single step.

7. The laptop stand of claim 1, wherein said upper and lower surface may be constructed from materials such as plastic (polyethylene, acrylic, recycled plastics), wood, glass, or some other material that is capable of meeting the physical demands required to accommodate various portable devices.

8. The laptop stand of claim 1, wherein voids are incorporated into the upper surface to assist in cooling the device by providing improved airflow.

9. The laptop stand of claim 1, wherein anti-slip inserts are installed onto the upper surface and onto the lower surface to ensure grip.

10. The laptop stand of claim 1, wherein anti-slide bars, or tabs, are used to further assist in securing a laptop on the upper surface and peripherals on the lower surface.

11. In an expandable apparatus:
An apparatus made from a material that is capable of meeting the physical demands required for supporting portable devices, that incorporates one or more segments which can be manipulated, providing the apparatus with the ability to be expanded or collapsed, that includes two ends which may form a connection with an upper surface and lower surface, whereby giving one the ability to adjust the portable device stand of claim 1 in a single step.

12. The expandable apparatus of claim 8 wherein said apparatus be composed of plastic due to its inherent strength, ability to be molded, price, resilience, flexibility and rigidity ratios.

13. The expandable apparatus of claim 8 wherein said apparatus have a wall thickness that accommodate ease of opening and closing, yet retain its ability to support the weight of the device and the surface it is connected to, whereby multiple expandable apparatus may be used to accommodate heavier items.

14. The expandable apparatus of claim 8 wherein said apparatus forms a connection with at least two surfaces upon being fastened by a fastener characterized by a helical ridge, or external thread, wherein said external thread forms a connection with the internal thread of a separate cap, wherein said cap communicates with the surfaces by either being molded in, or, connected through some other means.

15. The expandable apparatus of claim 8 wherein said apparatus may be presented in various colors, finishes, luster, and opacities.

16. The expandable apparatus of claim 8 wherein said apparatus have at least one expandable segment, providing the ability to raise or lower a surface that might be connected to said apparatus.

17. The expandable apparatus of claim 8 wherein said apparatus expands in an accordion style manner, where each segment is sufficiently rigid enough to support the weight of a portable device as well as use of and interface with said device without collapsing.
